(19) United States
(12) Patent Application Publication
(10) Pub. No.: US 2024/0237241 A1
(43) Pub. Date: Jul. 11, 2024

(54) FIELD DEVICE WITH RADIO MODULE AND METHOD FOR REMOTE DATA TRANSMISSION

(71) Applicant: VEGA Grieshaber KG, Wolfach (DE)

(72) Inventors: Martin Mellert, Steinach (DE); Natalie Waldecker, Ortenberg (DE); Robin Müller, Mühlenbach (DE)

(21) Appl. No.: 18/403,475

(22) Filed: Jan. 3, 2024

(30) Foreign Application Priority Data
Jan. 11, 2023 (EP) 23151077.7

(51) Int. Cl. H05K 5/02; H02G 3/22; H05K 9/00

(52) U.S. Cl. CPC H05K 5/0217; H02G 3/22; H05K 9/0081

(57) ABSTRACT

A field device, in particular, a fill-level, point-level, flow, pressure or temperature-measurement device, with a housing, an electrical connection line led into the housing via a cable feedthrough, and a radio module held in the housing for remote data transmission, wherein the radio module is arranged and designed in such a way as to transmit a remote data-transmission signal by means of a field coupling. A section of the connection line located in the housing transmits or receives signal into or out of a section of the connection line located outside the housing. The invention also relates to a method for remote data transmission by means of a radio module housed in a housing of a field device.

### CROSS REFERENCE TO RELATED APPLICATIONS

This Application claims priority from Application 23151077.7 filed on Jan. 11, 2023 in European Patent Office. The entire content of this application is incorporated herein by reference in its entirety.

### FIELD OF THE INVENTION

The invention relates to a field device with a radio module for remote data transmission held in a housing and a method for remote data transmission by means of a radio module held in a housing of a field device.

### BACKGROUND OF THE INVENTION

In process automation technology, field devices are often used to detect and/or influence process variables. Examples of such field devices include fill-level, point-level, flow, pressure, temperature-measurement devices and the like with sensors that detect the corresponding process variables fill level, point level, flow, pressure, temperature, etc. Such field devices are often connected to higher-level units, such as control systems or control units via remote data transmission. These higher-level units are used for process control, process visualization and/or process monitoring. Remote data transmission can take place both in a wired as well as a wireless manner.

Field devices with metallic housings are often used due to their mechanical stability and resistance to environmental influences. When field devices are used in potentially explosive environments, they must meet certain requirements that also require the use of metallic housings. Openings in the housing are designed in such a way that transmission of the explosion from the housing is prevented. All closures and bushings of the housing have to be designed accordingly and are therefore sometimes very complex to design.

It is well known to use radio modules for easier operation and parameterization of field devices. Operation and parameterization via radio modules makes it easier for the operating personnel to work on site since the field device does not have to be opened for parameterization, for example, and can have to be completely decommissioned. The radio modules can also be used for wireless remote data transmission with a higher-level unit.

However, the use of radio modules is at odds with metal housings. If a radio transmitter/receiver is located inside the field-device housing together with the other sensor electronics of a field device (e.g., fill-level or pressure sensor), metal housing walls prevent the propagation of electromagnetic waves and thus the desired radio connection.

The propagation of electromagnetic waves can also be prevented or at least significantly disturbed by a medium that at least partially surrounds the field device, in which the field device is immersed, for example, regardless of the selected housing material. For example, the medium can be water, oil, etc. (i.e., flowable), which significantly impedes the propagation of electromagnetic radiation. Bulk media, such as metal or metal-containing powder, granules or a combination of bulk and flowable media for example, which partially or completely surround the field device, can also significantly restrict or completely prevent a desired radio connection.

Against this background, the object of the invention is to provide a field device with a radio module for remote data transmission as well as a method for remote data transmission by means of such a field device, which overcomes the disadvantages known from prior art. In particular, the field device and the remote data transmission method should enable reliable data transmission, have a high level of operational reliability, be user-friendly, require a low level of maintenance and, last but not least, cost-effective in production or implementation.

### SUMMARY OF THE INVENTION

It should be pointed out that the features listed individually in the claims can be combined with each other in any technically sensible way (even across category boundaries, for example, between method and device) and show further embodiments of the invention. The description further characterizes and specifies the invention, especially in connection with the figures.

It should also be noted that a conjunction “and/or” used herein between two features and linking them must always be interpreted as meaning that only the first feature can be present in a first embodiment of the object according to the invention; only the second feature can be present in a second embodiment; and both the first as well as second features can be present in a third embodiment.

In addition, the term ‘approximately’ used herein is intended to indicate a range of tolerance which the person skilled in the art working in the present field considers to be common. In particular, the term “approximately” is to be understood as a tolerance range of up to a maximum of ±20%, preferably up to a maximum of ±10%.

According to the invention, a field device, for example, a fill-level, point-level, flow, pressure, temperature-measurement device or the like, comprises a housing, an electrical connection line led into the housing via a cable feedthrough, and a radio module for remote data transmission held in the housing. The radio module is arranged and designed in such a way to transmit and/or receive a remote data-transmission signal into/from a section of the connection line outside the housing by means of a field coupling with a section of the connection line located in the housing.

For the sake of simplicity, the section of the connection line located in the housing is also referred to as the internal line section and the section of the connection line outside the housing is also referred to as the external line section.

The electrical connection line can be used, for example, to power the field device, to ground it, or the like. Accordingly, the connection line comprises at least one electrically conductive lead.

In the broadest sense, a field coupling can be understood as an electrically non-contact, i.e., non-galvanically connected, coupling of two electronic components by means of an electric, magnetic or electromagnetic field (i.e., electromagnetic radiation), wherein the field coupling according to the invention is designed to ensure the transmission of the remote data-transmission signal between the radio module and the internal section of the connection line. In the simplest case, the radio module can be designed for unidirectional remote data transmission (i.e., either only transmit or only receive). Two-way remote data transmission (i.e., both sending as well as receiving) is also possible.

The invention enables remote data transmission or data communication with the field device via the inner and outer sections of the connection line, wherein a communication partner is located at a spatial distance from the field device. Regardless of the medium that partially or completely surrounds the field device, the remote data transmission can be routed from the field-device housing (and possibly from the medium) to the outside via the connection line.

The remote data-transmission signal can be tapped from a section of the external connection line. This means that a galvanic (i.e., electrically contacted) tapping can be carried out in order to detect (i.e., receive) the electrical signal on the connection line or to feed it into it (i.e., to transmit it). Alternatively, the tapping can be carried out in an electrically contact-free manner by means of a field coupling between the tap part of the external connection line and the spatially distant receiver or transmitter, meaning, in the broadest sense, by signal or data transmission using an electric, magnetic or electromagnetic field (i.e., via electromagnetic radiation). The field coupling at the external line section can be similar to the field coupling between the radio module and the internal line section but is not necessarily limited to this. The external field coupling can also be designed according to a different transmission principle than the internal field coupling.

If the external connection line comprises a cable insulation (e.g., plastic insulation), the section of the connection line intended for the tapping is preferably not insulated, regardless of whether the tapping or feeding of the remote data-transmission signal to the external connection line takes place in a galvanic manner or via field coupling.

The external line section can also comprise a plurality of sections where the remote data-transmission signal can be tapped or fed in.

Interception of the remote data-transmission signal is understood to mean both a decoupling (i.e., receiving) of the signal from the connection line as well as a coupling (i.e., sending) of a remote data-transmission signal from a transmitter on the outside of the housing in order to transmit the remote data-transmission signal between the inner line section and the external line section. In this way, bidirectional data transmission between the send/receiver external to the field device and the radio module or field device can be implemented.

Among other things, the invention enables user- and application-friendly operation and parameterization of the field device via the radio module since the field device does not have to be opened and, where applicable, taken out of operation for this purpose. The field device can remain in place during the operation or parameterization process. It is irrelevant whether the field device is already immersed in or surrounded by a medium (e.g., water, oil, granules, powder, etc.) or is not yet in contact with the medium. Likewise, the field-device housing can be made of a metal material without significantly interfering with remote data transmission. This is a particular advantage of the invention. However, field-device housings made of a non-metallic material, such as plastic, are by no means excluded and can be used as an alternative or supplement to a metal housing. Likewise, the field device can transmit measured values to the external receiver/transmitter (e.g., higher-level control centre or the like) during the intended operation by means of the remote data transmission disclosed herein.

Furthermore, the invention provides a compact field device in which the radio module can be fully integrated, and the remote data-transmission signal is transmitted via the connection line.

It should be understood that a field device designed as a fill-level, point-level, flow, pressure or temperature-measurement device also comprises a corresponding measurement transducer for detecting a fill level, point level, flow, pressure or temperature.

The field coupling can be developed as a capacitive and/or inductive coupling and/or as electromagnetic radiation coupling according to a preferred embodiment of the invention.

Capacitive coupling refers to the influence of an electric field on the electrical/electronic components involved, for example, coupling to parallel conductors in a cable or parallel-guided conductor paths on a printed circuit board. This effect can be used, for example, between parallel-routed lines with high-impedance terminating impedances.

Inductive coupling refers to the influence of a magnetic field on the electrical/electronic components involved. Inductive coupling is achieved by magnetic field coupling, usually in conductor loops, for example, between parallel-guided conductor loops, each of which can comprise low-impedance terminating impedances.

Radiation coupling refers to the process by which an electromagnetic field acts on the electrical/electronic components involved in the coupling, as in a radio transmission. Electrical conductors of a cable or on printed circuit boards can act as an antenna and receive or emit radio signals. Radiation coupling can occur between cable-cable, field-cable or antenna-antenna and, in the sense disclosed herein, can be used to transmit the remote data-transmission signal between the radio module and the internal line section of the connection line.

The field coupling between the radio module and the internal line section of the connection line offers the special advantage that the radio module, including an antenna for wireless data transmission, can be completely arranged and held in the field-device housing. Field coupling (i.e., capacitive, inductive or electromagnetic radiation) can be achieved by appropriate arrangement and design of the antenna and the internal line section. Field coupling can thus be realized without additional components and without special coupling circuits (e.g., circuit networks with resistors, capacitors, coils and the like).

For example, the antenna and the internal coupling section of the connection line can be designed as parallel conductors or parallel-guided conductor paths on a printed circuit board, but this is not necessarily limited to this. The antenna and the internal line section intended for coupling can also be designed as conductor loops.

In this sense, a favourable further embodiment of the object of the invention provides that the radio module comprises an antenna arranged in the housing, wherein the antenna and the section of the connection line within the housing are designed and arranged for the alternating field coupling. For example, the radio module is preferably designed for the use of NFC, RFID, DECT, Wi-Fi/WLAN or Bluetooth radio transmission technologies, without necessarily being limited to these technologies alone. It is to be understood that other radio transmission techniques can also be used, and the above list is to be understood only as an example and not as exhaustive. The antenna of the radio module is preferably fully integrated into the housing. The antenna and the internal section of the connection line can, for example, be designed and arranged as parallel conductors or parallel-guided conductor paths on a printed circuit board, wherein other embodiments and arrangements of the antenna and the internal line section which essentially achieve the same objective are not excluded.

In any case, the radio module (e.g., Bluetooth module) installed in the field device couples the radio signal or remote data-transmission signal into (i.e., transmit) or out of it (i.e., receive) the internal line section of the connection line. For example, the signal can be tapped at an open, non-insulated end of the connection line or a section of the connection line without shielding in the manner disclosed herein.

In order to make the remote data transmission less sensitive to external interference, the section of the connection line outside the housing comprises a transverse and/or longitudinally waterproof insulation according to a preferred further embodiment. For example, the insulation can be made of plastic.

In the case of transversely waterproof insulation, a liquid medium such as water, oil, etc. cannot penetrate the insulation for example and therefore cannot reach the electrically conductive electrical lead of the connection line used for the transmission of the remote data-transmission signal. Longitudinal waterproofing prevents a liquid medium such as water, oil and the like for example from penetrating through free ends of the insulation or, in the event of damage to the insulation, also between two free end sections between the insulation. The penetration of the liquid medium into other areas of the connection line is also prevented by longitudinal waterproofing.

In both cases, i.e., transverse and/or longitudinal waterproof insulation, damping of the remote data-transmission signal in the connection line is prevented as a result of contact between the connection line or electrical lead and the liquid medium.

The term “waterproof” is not intended to be limited to a sealing effect only with respect to the medium of water. Rather, a sealing effect of the insulation is to be understood against all those media with which the connection line may come into contact during the intended use of the field device and which in particular cause a detrimental (e.g., damping) effect on the transmission performance of the remote data-transmission signal via the connection line. These media can be flowable, such as water, oil, or the like for example, but also pourable, such as granular or powdery media.

The cable feedthrough can preferably be designed as a fluid-tight connection of the connection line to the housing.

As already mentioned elsewhere, in accordance with an embodiment of the invention, the section of the connection line located outside the housing can comprise at least one insulation-free section for decoupling and/or coupling the remote data-transmission signal.

At this section, the remote data-transmission signal can be picked up galvanically, capacitively, inductively or by electromagnetic radiation coupling from a receiver external to the field device or fed into an external transmitter. This means that there is a spatially separate tapping option or, if a plurality of insulation-free sections are provided, there are a plurality of tapping options for one or a plurality of external transmitters/receivers.

In a favourable further embodiment of the subject matter of the invention, the housing comprises an electromagnetically effective housing shielding. On the one hand, housing shielding can cause a concentration of the field between the radio module (e.g., antenna) and the internal line section of the connection line. In addition, the housing shielding can prevent or at least significantly dampen the irradiation of external interference fields into the housing. The housing shielding can be made of an electrically conductive material. For example, a plastic housing can comprise a metallic coating. This can be mounted on the outer side and/or inner side of the housing or embedded in housing walls.

The housing can also be partially or wholly made of a metal material that can provide a shielding function as an alternative to or in addition to a housing coating. For example, the housing can comprise a fully welded metal structure.

Depending on the specific design and intended use of the field device, it can be necessary not to completely enclose the housing and/or to form it fully metallic, for example in order not to shield or weaken the physical quantity to be held by a measurement transducer.

In general, a measurement transducer is to be understood as a part of the field device that reacts directly to the quantity to be measured.

In the present case, a window can be provided in the housing of the field device, through which the measurement transducer can detect the physical quantity essentially undisturbed. In order to achieve the shielding effect and/or field coupling concentration described above, if the field device comprises a non-metallic measurement transducer, such as a ceramic pressure transducer for example, this can be covered with a metallic measuring electrode on the inner side of the housing. The measuring electrode is used to convert the physical quantity held by the measurement transducer into a suitable electrical quantity (e.g., current, voltage). At the same time, the measuring electrode is used in a favourable way for electromagnetic shielding and/or field concentration.

Furthermore, the section of the connection line outside the housing can preferably comprise an electromagnetically effective cable shielding. This can be provided over the entire length of the external line section in order to prevent the coupling of external interference signals directly into the external connection line.

The length of the section of the connection line located outside the housing can be at least about 2 m, preferably at least about 3 m, and even more preferably at least about 5 m. The maximum length of the section of the connection line located outside the housing is preferably not more than a few hundred metres, e.g., about 100 to 500 m, preferably a maximum of about 50 to 100 m, and even more preferably, a maximum of about 15 to 50 m. It has been shown that, in this way, a reliable transmission of the remote data-transmission signal can be achieved between the radio module 6 on the inner side of the housing and a transmitter/receiver coupled to the outer section 10 of the connection line 5. The above lengths of the outer connection line indicate in particular the length of the outer connection line used for the transmission of the remote data-transmission signal, i.e., essentially a length from the end of the section of the connection line located outside the housing to a tapped section of the connection line furthest from the housing. In the case of a non-contact tapping, transmission distances of a few centimetres, for example, 10 cm to 50 cm up to a few metres, for example, up to about 10 m to 15 m, can be achieved by means of the remote data transmission according to the invention from the connection line (i.e., from a tapped section of the connection line) to a transmitter/receiver.

Furthermore, another favourable embodiment of the object of the invention provides that the connection line is designed as a support cable on which the housing is held suspended when the field device is in its operating state. For example, the field device can be designed as a suspended pressure gauge that is suspended at the site of use by means of the connection line. Of course, the embodiment as a support cable is not limited to pressure gauges. For example, a fill-level or point-level measurement device can be suspended in a container containing a medium to be monitored via the connection line, which is designed as a support cable. Likewise, other field measurement devices such as flow metres, temperature-measurement devices, etc. can also be suspended when in operation by means of their connection line, used as a support cable.

In accordance with a further aspect of the invention, a method for remote data transmission by means of a radio module held in a housing of a field device is disclosed via an electrical connection line led into the housing by means of a cable feedthrough, wherein a remote data-transmission signal is transmitted into and/or received out of a section of the connection line located outside the housing by means of a field coupling of the radio module with a section of the connection line located in the housing.

It is to be understood that with regard to method-related definitions of terms as well as the effects and advantages of features according to the method, the disclosure of analogous definitions, effects and advantages of the device according to the invention can be fully referenced. Correspondingly, disclosures herein with regard to the device according to the invention can also be used mutatis mutandis to define the method according to the invention so that, at this point, a repetition of explanations of analogous features of the same features, their effects and advantages is dispensed with in favor of a more compact description without such omissions being interpreted as a restriction.

According to a favourable embodiment of the method, the field coupling is carried out capacitively and/or inductively and/or by electromagnetic radiation.

In the case of electromagnetic radiation, the field coupling is carried out between an antenna of the radio module located in the housing and the section of the connection line inside the housing, which is designed and arranged for the alternating field coupling.

After a preferential further embodiment of the invention, the remote data-transmission signal is decoupled and/or coupled at least one part of the section of the connection line outside the housing by galvanic, capacitive and/or inductive coupling and/or by electromagnetic radiation coupling.

A still preferred embodiment of the method provides that the housing is held suspended via the connection line, which is designed as a support cable, when the field device is in its operating state.

It should be noted that in certain applications, as an alternative to the field coupling of the remote data-transmission signal according to the invention (e.g., capacitive, inductive or electromagnetic radiation) between the radio module and the section of the connection line located in the housing, a wired coupling of the remote data-transmission signal into the connection line section in the housing can also be possible. This is a galvanic, i.e., electrically contacted, coupling. For example, the electrical connection line can be designed as a coaxial cable or coaxial cable with an inner conductor and an outer conductor coaxially surrounding it, or it can also comprise such a coaxial cable that is dedicated to remote data transmission. In any case, the wired coupling can be carried out galvanically, for example to the inner conductor of the coaxial cable. The wired coupling between the radio module and the section of the connection line in the housing can prove to be favourable for longer lengths of the connection line that are greater than, for example, 10 m, e.g., 20 m, 50 m, 100 m and more. Wired coupling enables a low-damping transmission of the remote data-transmission signal between the radio module and the connection line, which can be provided for remote data transmission with less construction and/or operational effort when such connection line lengths are combined with certain radio transmission standards (e.g., Bluetooth). Non-contact field coupling in the sense according to the invention can also be possible in these cases.

### BRIEF DESCRIPTION OF THE DRAWINGS

Further features and advantages of the invention can be found in the following description of non-restrictive exemplary embodiments of the invention, which are explained in more detail below with reference to the drawing. In this drawing, schematically show:

FIG. 1 a functional diagram of an exemplary embodiment of a field device according to the invention,

FIG. 2 a partial view of a first example of a possible field coupling according to the invention,

FIG. 3 a partial view of a second example of a possible field coupling according to the invention,

FIG. 4 a partial view of a third example of a possible field coupling according to the invention,

FIG. 5 a functional diagram of another exemplary embodiment of a field device according to the invention and

FIG. 6 a functional diagram of yet another exemplary embodiment of a field device according to the invention.

In the different figures, parts that are equivalent in terms of their function are provided with the same reference numbers so that they are also usually described only once.

### DETAILED DESCRIPTION OF THE DRAWINGS

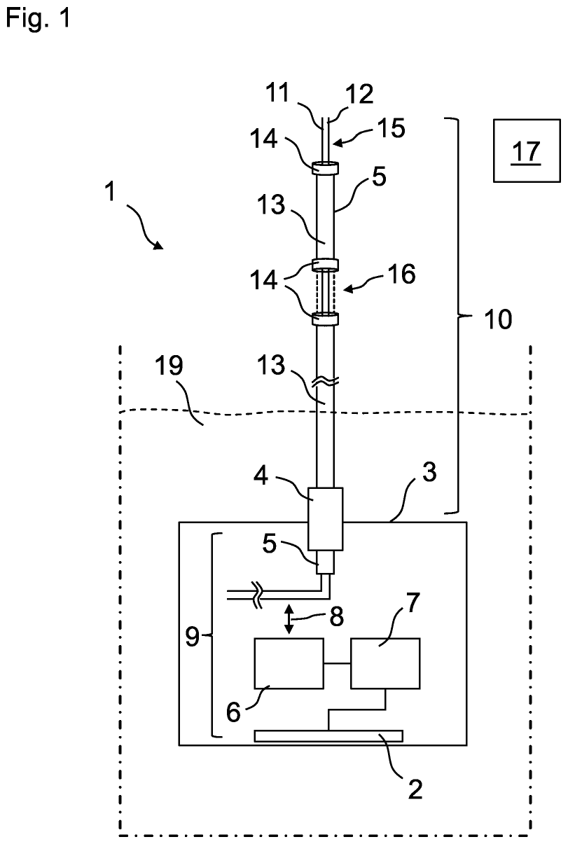

FIG. 1 schematically illustrates a functional diagram of an exemplary embodiment of a field device 1 according to the invention. The field device 1 can be designed without restriction of generality, for example, as a fill-level, point-level, flow, pressure, temperature-measurement device or the like, wherein it comprises a corresponding measurement transducer 2 for detecting a fill level, point level, flow, pressure, temperature and the like.

The measurement transducer 2 is generally to be understood as a part of the field device 1, which reacts directly to the quantity to be measured.

FIG. 1 shows that the field device 1 comprises a housing 3, an electrical connection line 5 led into housing 3 via a cable feedthrough 4 and a radio module 6 for remote data transmission held in housing 3.

In the example shown in FIG. 1, radio module 6 is connected to an electronic control unit 7. The control unit 7 can be equipped with a microprocessor, microcontroller, DSP or the like as well as a microprocessor. memory such as RAM, ROM, flash, and the like. In the case of the exemplary field device 1 shown in FIG. 1, the control unit 7 is connected to the measurement transducer 2 in order to receive the electronic signals output by the measurement transducer 2 and, where applicable, to process them, and in particular to transmit them by means of the radio module 6. The field device 1 or the control unit 7 can also be designed to receive data via radio module 6, which can be used, for example, to operate and parameterize the field device 1.

For remote data transmission, the radio module 6 in the field device 1 is arranged and designed in such a way as to transmit and/or receive a remote data-transmission signal by means of a field coupling 8 with a section 9 of the connection line 5 located in housing 3 into a section 10 of the connection line 5 located outside the housing 3.

As can be seen from FIG. 1, the connection line 5 in the present case comprises a plurality of electrical leads 11, 12, which can be used, for example, to power the field device 1, but without necessarily being limited to the number of leads shown in FIG. 1 or to the intended use described here. There can be more than the number of leads shown in FIG. 1 or less in the connection line 5. The connection line 5 can be used in addition to or as an alternative to the grounding field device 1. It is also conceivable to provide a separate lead exclusively for remote data transmission by means of the radio module 6.

Furthermore, the connection line 5 of the field device 1 shown in FIG. 1 comprises a transversely and longitudinally waterproof insulation 13 or 14 located outside the housing 3, although neither the transversely waterproof insulation 13 nor the longitudinally waterproof insulation 14 necessarily have to be provided for the implementation of the invention. However, at least the transversely waterproof insulation 13 is a preferred embodiment of the connection line 5. The insulation 13 can be formed by a plastic sheath of the connection line 5. The term “waterproof” is not intended to be limited to a sealing effect only with respect to the medium of water. Rather, a sealing effect of the insulation 13, 14 is to be understood in relation to all those media with which the connection line 5 can come into contact during the intended use of the field device 1 and which, in particular, comprise a detrimental (e.g., damping) effect on the transmission performance of the remote data-transmission signal via the connection line 5. These media can be flowable, such as water, oil, etc., as well as pourable, such as granular or powdery media, or a combination of both for example.

The cable feedthrough 4 is preferably a fluid-tight connection of the connection line 5 to the housing 3.

The inner section 9 of the connection line 5 is shown only in part and to the extent necessary for the understanding of the invention. It should be understood that, for example, control device 7 can be electrically connected to the connection line 5 in order to be supplied with electrical energy, for example. Where applicable, other electrical/electronic components of the field device 1 that are not shown in FIG. 1 can be electrically connected to the connection line 5.

Furthermore, it can be inferred from FIG. 1 that the section 10 of the connection line 5 located outside the housing 3 comprises at least one insulation-free section, in the present case, two sections 15, 16 for the decoupling and/or coupling of the remote data-transmission signal. In the present case, section 15 represents a free end of the connection line 5, while the section 16 is an intermediate piece of the connection line 5, which does not comprise any insulation. Of course, the number and arrangement of sections 15 and 16 are not limited to the form shown in FIG. 1. Less than two sections without insulation, but also more than two non-insulation sections can be provided in the external section 10 of the connection line 5.

The remote data-transmission signal can optionally be tapped at the insulation-free sections 15, 16. This means that a galvanic (i.e., contact) tap can be provided to detect (i.e., receive) or feed (i.e., transmit) the electrical signal on the connection line. Alternatively, the tapping can also be carried out electrically without contact by means of a field coupling (e.g., similar to field coupling 8) between the sections 15, 16 and a receiver and/or transmitter 17 external to the field device, i.e., in the broadest sense, by means of signal or data transmission using an electric, magnetic or electromagnetic field (i.e., electromagnetic radiation). In the case of non-contact tapping, transmission distances of a few centimetres, e.g., 10 cm to 50 cm, up to a few metres, e.g., up to about 10 m to 15 m, can be achieved by means of the remote data transmission according to the invention from the tap 15 or 16 to a transmitter/receiver 17 without necessarily being limited to the concrete embodiment of the field device 1 from FIG. 1.

In addition to insulation 13 and/or 14, the connection line 5 or at least the section 10 of the connection line 5 located outside the housing 3 can comprise an electromagnetically effective line shielding (not shown).

The external section 10 of the connection line 5 can have a length of at least about 2 m, preferably at least about 3 m, even more preferably at least about 5 m and a maximum length of not more than about 50 m, preferably not more than about 25 m and even more preferably not more than about 15 m. Lengths of the connection line 5 at a range between about 2 m and about 50 m are also included. Depending on the specific application, for example, as a suspended pressure sensor, the external section 10 of the connection line 5 (i.e., the outer section used for remote data transmission) can also have lengths of up to a few hundred metres, for example, about 100 m to 500 m, wherein a maximum length of no more than about 50 to 100 m or even less (e.g., a maximum of about 15 m to 50 m) can be particularly favourable, to ensure reliable remote data transmission according to the invention.

As can be further deduced from FIG. 1, the connection line 5 in the present example is designed as a support cable on which the housing 3 is held suspended when the field device 1 is in its operating state. For example, the field device 1 can have been suspended in a medium in a container 19 (at least partially), as indicated in FIG. 1 by dashed or dotted lines. For example, field device 1 can be designed as a pendant pressure sensor without necessarily being limited to the specific embodiment as a pressure sensor. The field device 1 can also be designed as a fill-level, point-level, flow, temperature-measurement device or the like and can be suspended at the site of operation via a connection line 5.

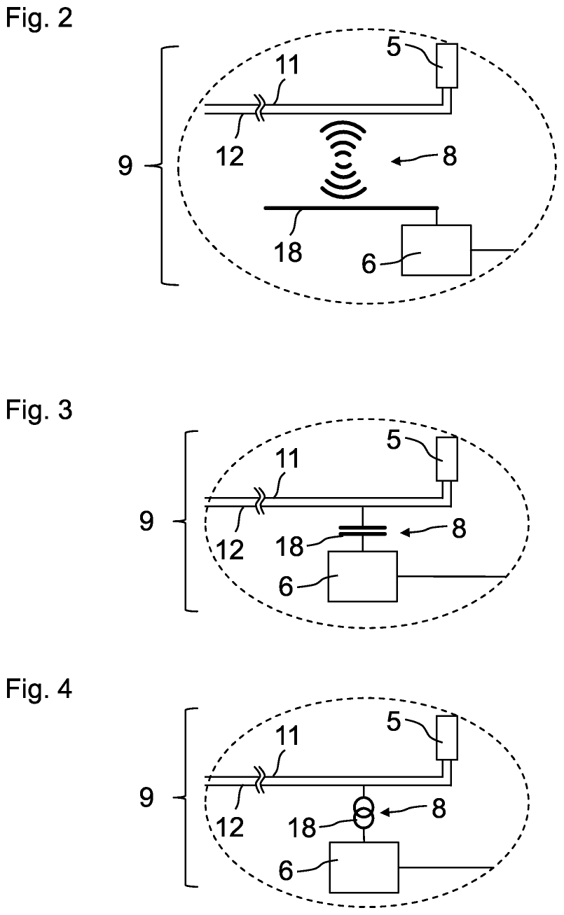

Preferably, the field coupling 8 of the field device 1 is designed as capacitive and/or inductive coupling and/or electromagnetic radiation coupling. FIGS. 2, 3 and 4 each schematically illustrate examples of such a field coupling 8 in a partial view, as it can be used in field device 1 of FIG. 1, but also in possible further embodiments of a field device according to the invention.

In FIG. 2, field coupling 8 is shown schematically in the form of an electromagnetic radiation coupling. As can be seen, in radiation coupling, an electromagnetic field acts on the electrical/electronic components involved in the coupling, as in radio transmission. In the present case, these include the antenna 18 of radio module 6 as well as the internal section 9 of the connection line 5 or leads 11 and/or 12.

The field or radiation coupling between the radio module 6 and the internal line section 9 of the connection line 5 offers the particular advantage that the radio module 6 including the antenna 18 can be completely arranged and held in the field-device housing 3. The radiation coupling is realized by the appropriate arrangement and formation of antenna 18 and/or the internal line section 9 of the connection line 5. Field coupling 8 can be implemented without additional components, especially without special coupling circuits (e.g., circuit networks with resistors, capacitors, coils and the like).

The antenna 18 and the internal coupling section 9 of the connection line 5 can be designed as parallel conductors or parallel-guided conductor paths on a printed circuit board, without necessarily being limited to such an arrangement or embodiment.

In FIG. 3, field coupling 8 is shown schematically in the form of a capacitive coupling. In this case, the electrical/electronic components involved are influenced by an electric field as a result of an over-coupling to parallel conductors in a cable or parallel-guided conductor paths on a printed circuit board. Instead of, or in addition to, the antenna 18 in FIG. 2, a corresponding conductor can be connected to the remote-data-transmission output of radio module 6, which is arranged to the internal section 9 of the connection line 5. The conductor or antenna 8 can be designed as a conductor path on a printed circuit board, as well as the internal line section 9.

In FIG. 4, the field coupling 8 is schematically illustrated in the form of an inductive coupling. In inductive coupling, the electrical/electronic components involved influence each other through a magnetic field. Inductive coupling is achieved by magnetic field coupling, usually in conductor loops, for example, between parallel-guided conductor loops. Instead of, or in addition to, the antenna 18 in FIG. 2, a corresponding conductor loop can be connected to the remote data transmission output of radio module 6, which is arranged accordingly to the inner section 9 of the connection line 5, which is also designed as a guide loop in the same way. It is also possible to arrange and design as conductor loops on a printed circuit board.

In all the cases described above, radio module 6 can comprise an antenna 18 arranged in the housing 3, wherein the antenna 18 and the section 9 of the connection line 5 located within housing 3 are designed and arranged for the alternating field coupling 8. For example, the radio module is preferably designed for the use of radio transmission technologies such as NFC (Near Field Communication), RFID (Radio Frequency Identification), DECT (Digital Enhanced Cordless Telecommunications), Bluetooth, Wi-Fi/WLAN or the like for example without necessarily being limited to these technologies alone. Other radio transmission techniques are also conceivable, provided that they can be used for field coupling 8 as defined in the invention. The antenna 18 of the radio module 6 is preferably fully held in the housing 3. The antenna 18 and the inner section 9 of the connection line 5 may, for example, be designed as parallel conductors or parallel-guided conductor paths on a printed circuit board, wherein other embodiments and arrangements of the antenna 18 and the inner line section 9 are also possible, provided that the field coupling 8 is achieved with them in the sense according to the invention.

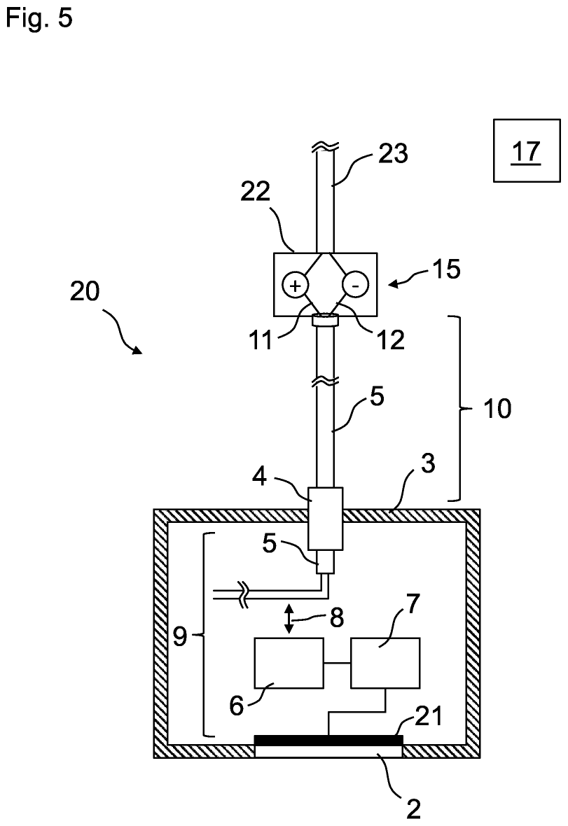

FIG. 5 shows a functional diagram of yet another exemplary embodiment of a field device 20 according to the invention. The field device 20 can basically be constructed in the same way as the field device 1 shown in FIG. 1. In the following, therefore, only the differences between field device 20 and field device 1 are explained.

The housing 3 of the field device 20 shown in FIG. 5 is made of a metal material. The measurement transducer 2, for example a ceramic pressure transducer, is located in a recess or window of housing 3. In the present exemplary embodiment, on the inner side of the housing, the non-metallic measurement transducer 2 comprises a metallic measuring electrode 21 on the inner side of the housing, which partially or completely occupies the measurement transducer 2 to the interior of the housing 3. In this way, an optimal electromagnetic shielding effect of the field device 20 can be achieved, which is achieved by the metal housing 3 in combination with the metal electrode 21. The shielding effect can also be used to increase the efficiency of the field coupling 8 by concentrating or focusing the field distribution for field coupling 8 on a predetermined spatial region.

In the exemplary embodiment of the field device 20 shown in FIG. 5, the exposed (non-insulated) section 15 of the connection line 5 is a free end of the connection line 5, which can be connected to a further line 23 (e.g., supply line) in a junction or terminal box 22, for example. At this terminal box 22, the data-transmission signal can be tapped, i.e., received by receiver 17, or fed in, i.e., sent from transmitter 17 to radio module 6.

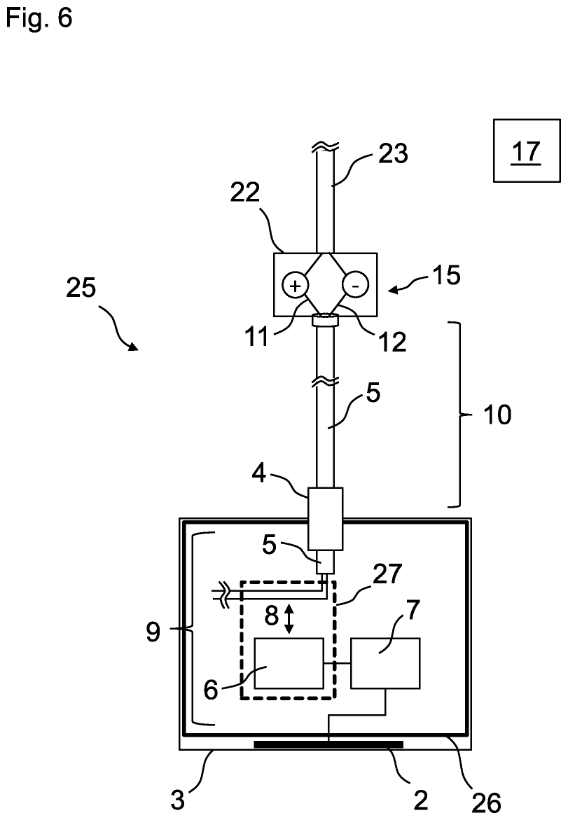

FIG. 6 shows a functional diagram of yet another exemplary embodiment of a field device 25 according to the invention. In principle, field device 25 can be constructed in the same way as field device 1 shown in FIG. 1. In the following, therefore, only the differences between field device 25 and field device 1 are presented.

In the present case, the housing 3 of the field device 25 is made of a plastic (e.g., polyvinylidene fluoride, PVDF). In order to improve the electromagnetic shielding effect, the housing 3 comprises an electromagnetically effective housing shielding 26, which can be formed, for example, from a metal layer attached to housing 3. In the present case, the housing shielding 26 is attached to the inner side of the housing. Housing shielding 26 can be mounted alternatively or additionally on the outside of the housing or embedded in the housing walls. Electromagnetic housing shielding 26 can cause a concentration of the field for field coupling. The housing shielding 26 can also prevent or dampen the irradiation of external interference fields into the housing 3 or the interior of the housing.

FIG. 6 also shows that in addition to or as an alternative to the housing shielding 26, an electromagnetically effective housing shielding 27 can be provided closer to the location of the actual field coupling 8 in order to further concentrate/focus the field distribution for the field coupling on a predetermined volume of space. Such housing shielding 27 designed and arranged in this manner is also conceivable in conjunction with other exemplary embodiments of the field devices according to the invention, for example, such as in the case of field devices 1 and 20 shown in FIGS. 1 and 5 respectively.

The field device according to the invention as well as the data transmission method according to the invention are not limited to the specific embodiments described herein, but also include similar further embodiments resulting from technically meaningful further combinations of the features of all the objects of the invention described herein. In particular, the features and combinations of features mentioned above in the general description and the description of the figures and/or shown in the figures alone are usable not only in the combinations explicitly stated herein, but also in other combinations or in a unique position, without leaving the scope of the present invention.

For example, the remote data-transmission signal can be coupled to a separate additional lead of the connection line. This lead can only be used for remote data transmission and cannot otherwise perform any other electrical function.

It is also conceivable to integrate the radio module directly into the connection line. For example, the radio module can be integrated into the inner section of the connection line. For example, the radio module can be surrounded by insulation of the connection line and mechanically connected to the connection line.

### Reference List

1 field device
2 measurement transducer
3 housing
4 cable feedthrough
5 connection line
6 radio module
7 control unit
8 field coupling
9 internal line section
external line section
11 lead
12 lead
13 transversely waterproof insulation
14 longitudinally waterproof insulation
15 insulation-free section
16 insulation-free section
17 receiver/transmitter external to the field device
18 antenna
19 medium
20 field device
21 metal electrode
22 junction/terminal box
23 continuing line
25 field device
26 housing shielding
27 housing shielding

1. A field device, in particular, a fill-level, point-level, flow, pressure or temperature-measurement device, with a housing, an electrical connection line led into the housing via a cable feedthrough and a radio module held in the housing for remote data transmission, wherein the radio module transmits or receives a remote data-transmission signal by means of a field coupling with a section of the connection located in the housing into or out of a section of the connection line located outside the housing.

2. The field device according to claim 1,
characterized in that
the field coupling is designed as capacitive and/or inductive coupling and/or electromagnetic radiation coupling.

3. The field device according to claim 1, characterized in that
the radio module comprises an antenna arranged in the housing, wherein the antenna and the section of the connection line located within the housing are designed and arranged for the alternating field coupling.

4. The field device according to claim 1, characterized in that
the section of the connection line outside the housing comprises transversely and/or longitudinally waterproof insulation.

5. The field device according to claim 4, characterized in that
the section of the connection line located outside the housing comprises at least one insulation-free section for decoupling and/or coupling the remote data-transmission signal.

6. The field device according to claim 1, characterized in that
the housing comprises an electromagnetically effective housing shielding.

7. The field device according to claim 1, characterized in that
the housing is made of a metal material.

8. The field device according to claim 1, characterized in that
a non-metallic measurement transducer is equipped with a metallic measuring electrode on the inner side of the housing.

9. The field device according to claim 1, characterized in that
the section of the connection line outside the housing comprises an electromagnetically effective line shielding.

10. The field device according to claim 1, characterized in that
the section of the connection line located outside the housing has a length of at least 5 m, and the maximum length of the section of the connection line located outside the housing is not more than 50 m.

11. The field device according to claim 1, characterized in that
the connection line is designed as a support cable on which the housing is suspended when the field device is in its operating state.

12. A method for remote data transmission by means of a radio module held in a housing of a field device via an electrical connection line via a cable feedthrough into the housing, wherein a remote data-transmission signal is transmitted by means of a field coupling of the radio module with a section of the connection line located in the housing into a section of the connection line located outside the housing and/or is received by this.

13. The method according to claim 12, characterized in that
the field coupling is carried out in a capacitive and/or inductive manner and/or via electromagnetic radiation.

14. The method according to claim 12,
characterized in that
the remote data-transmission signal is decoupled and/or coupled at least one section of the section of the connection line located outside the housing via galvanic, capacitive and/or inductive coupling and/or via electromagnetic radiation coupling.

15. The method according to claim 12,
characterized in that
when the field device is in its operating state, the housing is held suspended by the connection line as a support cable.
